(19) United States
(12) Patent Application Publication
(10) Pub. No.: US 2026/0186403 A1
(43) Pub. Date: Jul. 2, 2026

(54) IMPRINT APPARATUS AND METHOD THEREOF

(71) Applicant: TAIWAN SEMICONDUCTOR MANUFACTURING COMPANY, LTD., Hsinchu (TW)

(72) Inventors: Hsuan-Chin LU, Hsinchu City (TW); Yu-Luen DENG, Tainan City (TW); Chih-Kai YANG, Taipei City (TW); Ming-Feng SHIEH, Tainan County (TW); Hua-Tai LIN, Hsinchu City (TW); Meng-Jung LEE, Hsinchu City (TW); Chien-Cheng CHEN, Hsinchu County (TW)

(73) Assignee: TAIWAN SEMICONDUCTOR MANUFACTURING COMPANY, LTD., Hsinchu (TW)

(21) Appl. No.: 19/004,992

(22) Filed: Dec. 30, 2024

(51) Int. Cl. G03F 7/00; B25J 9/00

(52) U.S. Cl. CPC G03F 7/0002; B25J 9/0084

(57) ABSTRACT

A method includes performing imprint processes in imprint chambers of an imprint tool; performing an inspection process to a first imprint mask in at least one inspection chamber of the imprint tool; performing a cleaning process to a second imprint mask in at least one cleaning chamber of the imprint tool; transferring the second imprint mask from the at least one cleaning chamber to a mask library of the imprint tool; transferring the first imprint mask from the at least one inspection chamber to the cleaning chamber; transferring a third imprint mask from a first one of the imprint chambers to the at least one inspection chamber; and transferring a fourth imprint mask from the mask library to the first one of the imprint chambers.

### BACKGROUND

A photolithography or lithography apparatus is a machine that applies a desired pattern onto a semiconductor substrate, usually onto a target portion of the substrate. A lithography apparatus can be used, for example, in the manufacture of integrated circuits (ICs). In that instance, a patterning member, such as a mask, may be used to generate a circuit pattern to be formed on an individual layer of the IC. The circuit pattern can be transferred onto a target portion (e.g. comprising one or more dies) on a substrate (e.g. a silicon wafer). Transfer of the pattern is typically achieved via imaging onto a layer of radiation-sensitive material (i.e. photoresist) provided on the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 4 are schematic views of an imprint chamber at various stages of performing an imprint lithography process in accordance with some embodiments of the present disclosure.

FIG. 5 is a schematic view of an imprint mask inspection chamber in accordance with some embodiments of the present disclosure.

FIG. 6 is a schematic view of an imprint mask cleaning chamber in accordance with some embodiments of the present disclosure.

FIG. 7 is a method of designing an imprint tool in accordance with some embodiments of the present disclosure.

FIG. 8 is a schematic view of an imprint tool in accordance with some embodiments of the present disclosure.

FIG. 9 is a schematic view of an imprint tool in accordance with some embodiments of the present disclosure.

FIGS. 10 to 12 illustrate schematic views of an imprint tool at various stages of operating the imprint tool in accordance with some embodiments of the present disclosure.

FIG. 13 is a schematic view of an imprint tool in accordance with some embodiments of the present disclosure.

FIG. 14 is a block diagram of an imprint tool in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Imprint lithography, a technique utilized within the semiconductor manufacturing industry, involves the definition of patterns on a substrate using a mold or template. This process begins with the application of an imprint resist onto the substrate, which is typically a silicon wafer. The resist material, often a polymer, is selected based on its ability to undergo phase changes enabling imprinting. A mold, often fabricated from a durable and rigid material such as quartz, with nanoscale features, is positioned above the resist-covered substrate. The mold is then pressed onto the resist, exerting controlled pressure to ensure the imprint accurately transfers the pattern of the mold features into the imprint resist.

Following the application of pressure, a curing step is employed to solidify the resist material, thereby permanently capturing the pattern. Ultraviolet (UV) radiation is commonly used for this curing step when the resist is UV-sensitive, causing the polymer chains within the resist to cross-link and harden. Once the resist solidifies, the mold is delicately removed, leaving behind a detailed relief pattern in the imprint resist. Subsequent processing might involve etching steps to transfer the patterned resist features into the underlying substrate, typically through reactive ion etching (RIE). This process allows for the replication of nanometer-scale structures across large areas, proving invaluable in the production of various semiconductor devices.

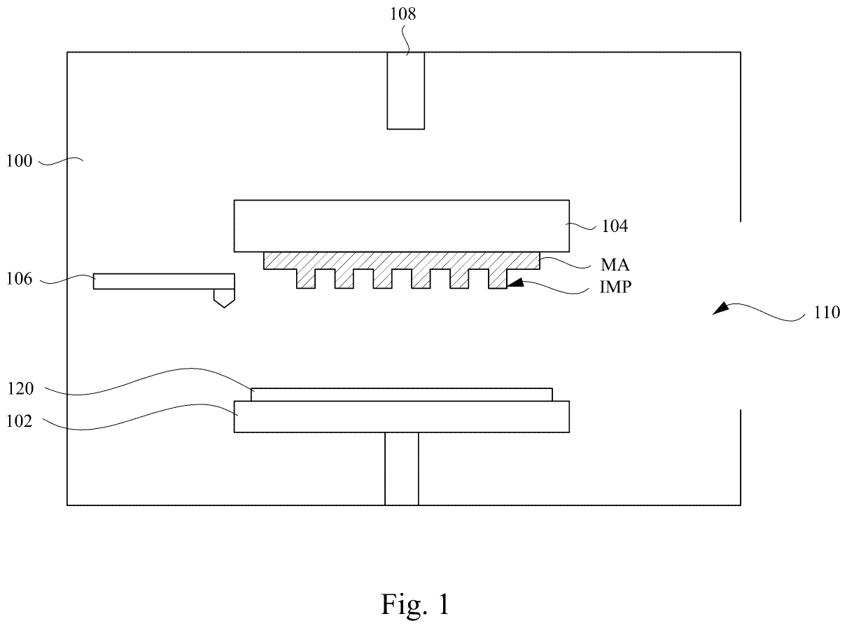

FIGS. 1 to 4 are schematic views of an imprint chamber at various stages of performing an imprint lithography process in accordance with some embodiments of the present disclosure. Shown there is an imprint chamber 100. In some embodiments, the imprint chamber 100 includes a wafer stage 102, a mask stage 104, a dispenser 106, and an irradiation source 108.

As shown in the imprint chamber 100 of FIGS. 1 to 4, an imprint mask MA is held by the mask stage 104. Here, term “imprint mask” can interchangeably be referred to as a mold or a template. In some embodiments, the imprint mask MA may be a transparent member having a desired imprint pattern IMP at its surface facing the wafer stage 102, and is disposed on the mask stage 104. Here, the imprint pattern IMP may be protrusion features protruded from a surface of the imprint mask MA. The surface of the imprint mask MA is meticulously fabricated using advanced lithography and etching techniques to create the protrusion features that can range from a few nanometers to several micrometers in size. These features are often arranged in complex geometries to meet the precise design requirements of the semiconductor device being manufactured.

In some embodiments, the material for the imprint mask MA can be appropriately selected from transparent materials capable of transmitting light having a wavelength of 200 nm or less, such as quartz, sapphire, fluorite, magnesium fluoride, lithium fluoride, or the like. In some embodiments, light with a wavelength of about 150 nm or more is transmissible when quartz or sapphire is used, light with a wavelength of about 130 nm or more is transmissible when fluorite is used, light with a wavelength of about 115 nm or more is transmissible when magnesium fluoride is used, and light with a wavelength of about 100 nm or more is transmissible when lithium fluoride is used. Further, it is also possible to use two or more species of materials for the imprint mask MA. In other embodiments, the material for the imprint mask MA may include metal, such as nickel.

The structural design of the imprint mask MA is engineered to ensure uniform pressure distribution across its surface during imprinting, which is essential for achieving consistent pattern replication across the substrate. In addition to the precise topographical features, the surface of the imprint pattern IMP may be treated with anti-sticking monolayers, such as fluorosilane coatings, to minimize adhesion between the imprint mask MA and an imprint resist. This treatment facilitates the clean release of the imprint mask MA from the hardened resist, preserving the integrity of the imprinted patterns and extending the functional lifespan of the imprint mask MA.

The mask stage 104 is disposed in the imprint chamber 100 and is movable. Accordingly, the mask stage 104 can move the imprint mask MA downwardly toward the wafer stage 102, and may be able to press the imprint mask MA against an imprint resist on a substrate. In some embodiments, the mask stage 104 may include pressure application mechanism, which may involve pneumatic, hydraulic, or piezoelectric actuators, to uniformly apply force needed for the imprint mask MA to imprint its pattern onto an imprint resist.

The dispenser 106 is disposed in the imprint chamber 100 and is movable. Accordingly, an imprint resist can be applied on to a surface of a substrate through the dispenser 106. In some embodiments, the imprint resist may include photocurable resin material capable of being cured by irradiation with light of a specific wavelength.

The irradiation source 108 is disposed in the imprint chamber 100, and may be positioned above the wafer stage 102. The irradiation source 108 is configured to generate irradiation toward a substrate disposed on the wafer stage 102 for curing an imprint resist on the substrate.

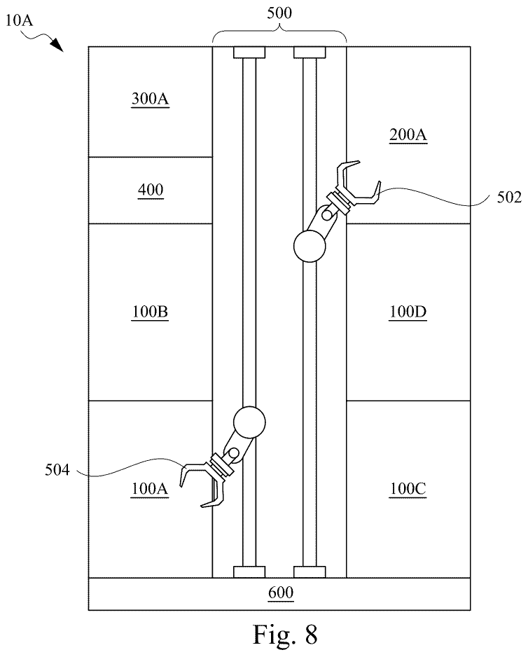

The imprint chamber 100 further includes a gate 110, which is spatially communicated with a transferring chamber (e.g., the transferring chamber 500 of FIG. 8), allowing the transfer of the imprint mask MA between the imprint chamber 100 and other chambers in an imprint tool.

Reference is made to FIG. 1. A substrate 120 is transferred into the imprint chamber 100 and is placed on the wafer stage 102, for example, from a transfer chamber through the gate 110 of the imprint chamber 100. In some embodiments, the wafer stage 102 is a vacuum chuck that applies a suction force to secure the substrate 120. The wafer stage 102, however, may be any chuck including, but not limited to, vacuum, pin-type, groove-type, electromagnetic, and/or the like.

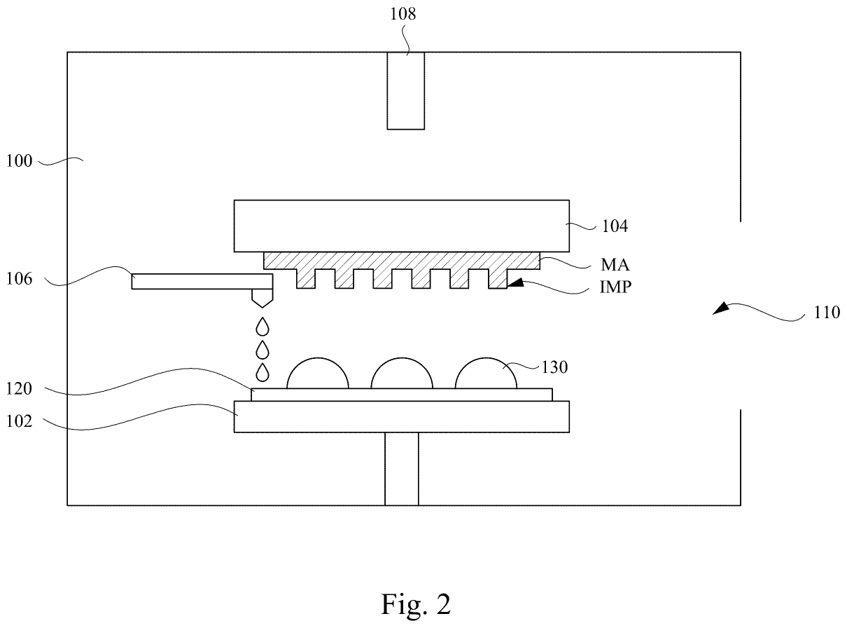

Reference is made to FIG. 2. Imprint resist 130 is deposited over the top surface of the substrate 120. For example, the dispenser 106 is moved, such that a nozzle of the dispenser 106 is vertically above the top surface of the substrate 120, and the imprint resist 130 can be dispensed over the top surface of the substrate 120 through the nozzle of the dispenser 106. In a drop dispense method, imprint resist 130 is disposed on the substrate 120 in the form of discrete, spaced-apart drops, as depicted in FIG. 2. In other embodiments, the imprint resist 130 may be dispensed upon the substrate 120 using techniques such as drop dispense, spin-coating, dip coating, chemical vapor deposition (CVD), physical vapor deposition (PVD), thin film deposition, thick film deposition, or the like.

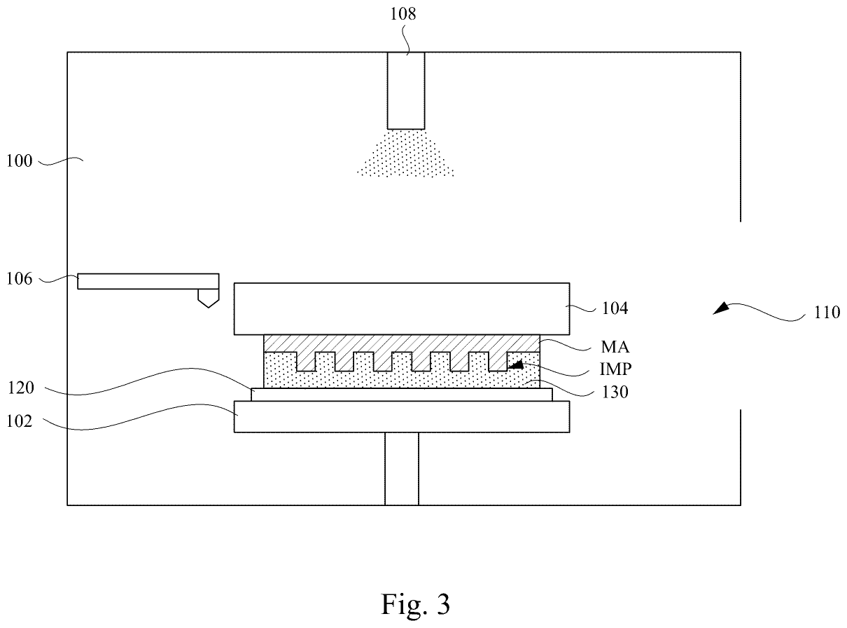

Reference is made to FIG. 3. The mask stage 104 is moved downwardly toward the substrate 120, so as to apply a force to the imprint mask MA, such that the imprint pattern IMP of the imprint mask MA press against the imprint resist 130. After the desired volume is filled with imprint resist 130, the irradiation source 108 produces energy (e.g., radiation or thermal energy), causing imprint resist 130 to solidify (e.g., polymerize and/or crosslink), conforming to the shape of the imprint resist 130 and the imprint pattern IMP of the imprint mask MA.

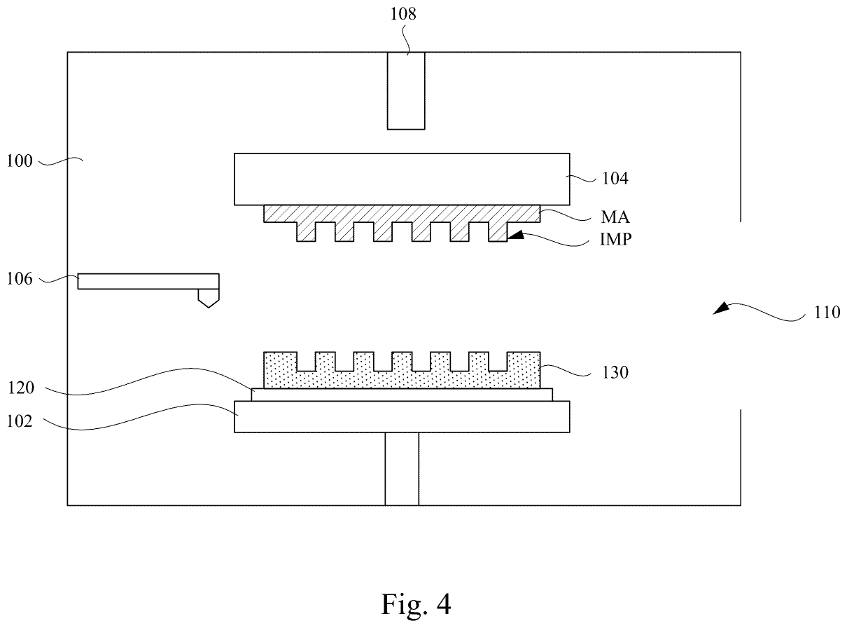

Reference is made to FIG. 4. The mask stage 104 is moved upwardly, so as to separate the imprint mask MA from the imprint resist 130 on the substrate 120, which has been patterned and cured during the operation as discussed in FIG. 3. Once the imprint resist 130 on the substrate 120 has been patterned, the substrate 120 can be removed from the imprint chamber 100 through the gate 110 of the imprint chamber 100. Afterwards, another substrate 120 can be transferred into the imprint chamber 100, and an imprint process can be performed to the other substrate 120.

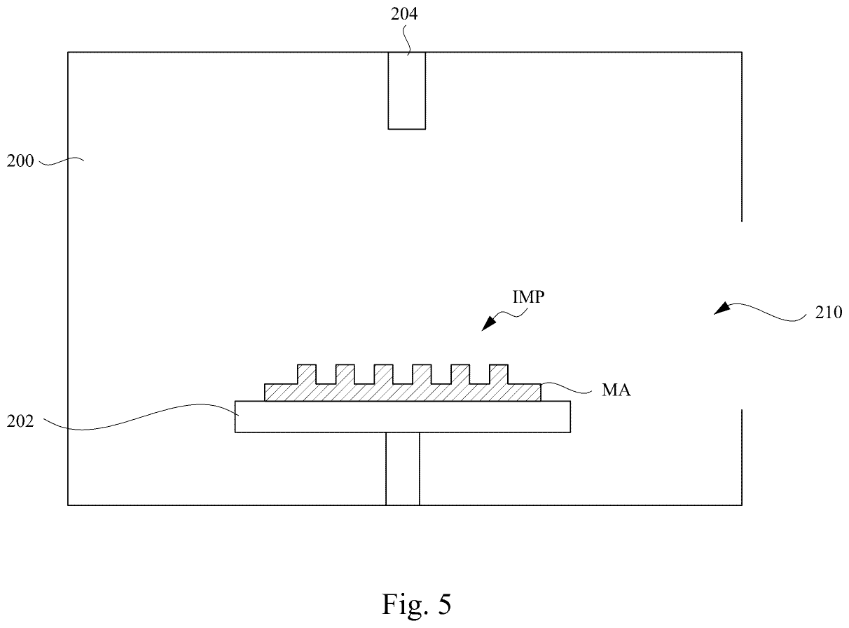

FIG. 5 is a schematic view of an imprint mask inspection chamber in accordance with some embodiments of the present disclosure. In some embodiments, because the imprint process is a contact-type lithography process by pressing an imprint mask (e.g., the imprint mask MA discussed in FIGS. 1 to 4) against an imprint resist over a substrate (e.g., the imprint resist 130 discussed in FIGS. 1 to 4), defects such as contamination (e.g., resist residue), scratches, or pitting may be easily occurred on the surface of the imprint mask. Accordingly, an inspection process of the imprint mask is needed to determine whether defects occur on the surface of the imprint mask.

In FIG. 5, shown there is an imprint mask inspection chamber 200. The imprint mask inspection chamber 200 may include a mask stage 202 and an image sensor 204. In some embodiments, once the imprint mask MA undergoes several imprint processes as discussed in FIGS. 1 to 4, the imprint mask MA may be transferred from the imprint chamber 100 as discussed in FIGS. 1 to 4 to the imprint mask inspection chamber 200 of FIG. 5. The imprint mask MA is secured on the mask stage 202, such that the imprint pattern IMP of the imprint mask MA may face the image sensor 204.

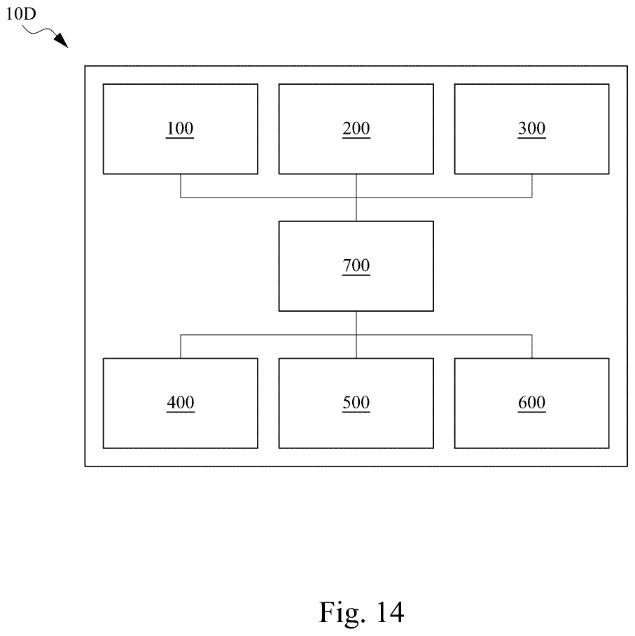

The image sensor 204 can capture an image of the imprint mask MA. Based on the captured image, one can determine whether defects occur on the imprint mask MA. For example, defects on the imprint mask MA can be determined through visual examination. In other example, the image sensor 204 can capture an image of an ideal imprint mask (e.g., a clean imprint mask that has not been used) to generate a reference image. The image of the imprint mask MA captured by the image sensor 204 is compared with the reference image through a control system (e.g., the control system 700 in FIG. 14), and defects can be determined based on the difference between the image of the imprint mask MA and the reference image.

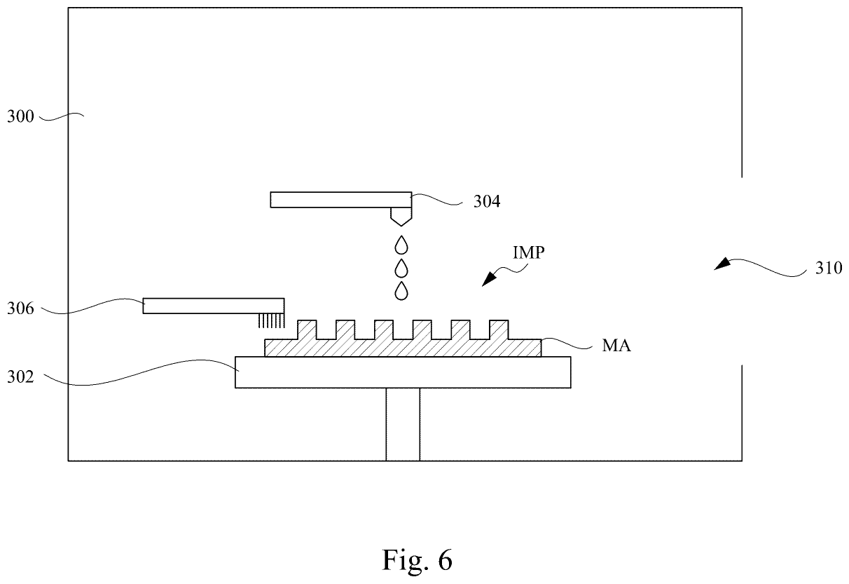

If defects occur on the imprint mask MA, the imprint mask MA may be transferred to an imprint mask cleaning chamber (e.g., the imprint mask cleaning chamber 300 of FIG. 6) and a cleaning process may be performed on the imprint mask MA to remove the defects on the imprint mask MA.

In some embodiments, an electrons beam inspection (EBI) may be used for the inspection of the imprint mask MA. For example, the image sensor 204 may be an electron gun, which generates a focused beam of electrons onto the surface of the imprint mask MA. As the electron beam interacts with the imprint mask MA, secondary electrons are emitted from the surface. These emissions are detected and analyzed to form high-resolution image of the surface of the imprint mask MA.

The imprint mask inspection chamber 200 further includes a gate 210, which is spatially communicated with a transferring chamber (e.g., the transferring chamber 500 of FIG. 8), allowing the transfer of the imprint mask MA between the imprint mask inspection chamber 200 and other chambers in an imprint tool.

FIG. 6 is a schematic view of an imprint mask cleaning chamber in accordance with some embodiments of the present disclosure. Shown there is an imprint mask cleaning chamber 300. The imprint mask cleaning chamber 300 may include a mask stage 302, a dispenser 304, and a brush 306. In some embodiments, if the imprint mask MA is determined as having defects, the imprint mask MA may be transferred from the imprint mask inspection chamber 200 of FIG. 5 to the imprint mask cleaning chamber 300 of FIG. 6. The imprint mask MA is secured on the mask stage 302, such that the imprint pattern IMP of the imprint mask MA may face upwardly.

The imprint mask cleaning chamber 300 is configured to clean the imprint mask MA. During the cleaning process, the dispenser 304 may be configured to supply a cleaning material to the surface of the imprint pattern IMP of the imprint mask MA, which may be used to remove defects, such as resist residue (e.g., imprint resist 130) left on the imprint pattern IMP of the imprint mask MA during the imprint process performed in FIGS. 1 to 4. In some embodiments, the cleaning material may include ozonized DI water, solvent, isopropyl alcohol (IPA), methanol, ammonia solution. On the other hand, the brush 306 may be coupled to an actuator (not shown) that moves the brush to clean the periphery region of the imprint mask MA. That is, the dispenser 304 is used to clean the imprint pattern IMP at the center region of the imprint mask MA, and the brush 306 is used to clean the periphery region of the imprint mask MA.

The imprint mask cleaning chamber 300 further includes a gate 310, which is spatially communicated with a transferring chamber (e.g., the transferring chamber 500 of FIG. 8), allowing the transfer of the imprint mask MA between the imprint mask cleaning chamber 300 and other chambers in an imprint tool.

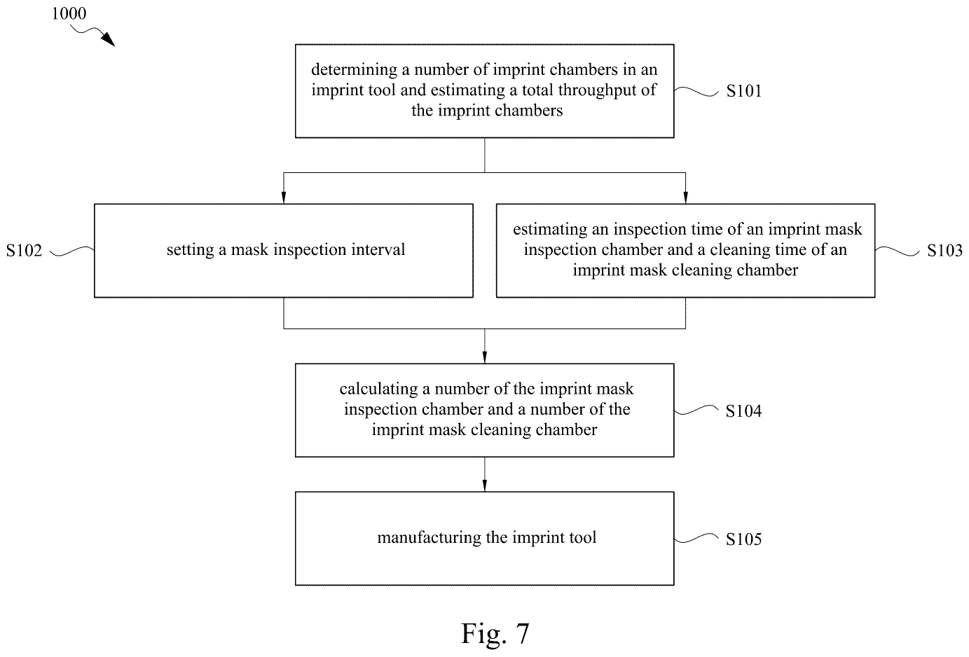

FIG. 7 is a method of designing an imprint tool in accordance with some embodiments of the present disclosure. FIG. 8 is a schematic view of an imprint tool in accordance with some embodiments of the present disclosure. Embodiments of the present disclosure provide a method 1000 for designing an imprint tool (or imprint apparatus), and the method 1000 will be discussed in conjunction with the imprint tool 10A as shown in FIG. 8. Specifically, the method 1000 is used to design an all-in-one (AIO) nano imprint lithography (NIL) tool by integrating imprint chambers, at least one imprint mask inspection chamber, at least one imprint mask cleaning chamber, a mask library, and a transferring chamber in a single imprint tool.

The method 1000 starts from operation S101 by determining a number of imprint chambers in an imprint tool and estimating a total throughput of the imprint chambers. At the beginning of designing an imprint tool, a number of the imprint chambers will be determined first. For example, the imprint tool may be designed to have N imprint chambers. For example, as shown in FIG. 8, the imprint tool 10A is designed to have four imprint chambers 100A, 100B, 100C, and 100D. Here, the imprint chambers 100A, 100B, 100C, and 100D may be similar to the imprint chamber 100 as discussed in FIGS. 1 to 4, and thus relevant details will not be repeated for brevity.

Generally, the imprint chambers 100A, 100B, 100C, and 100D are the same, namely with the same configuration. Accordingly, the imprint chambers 100A, 100B, 100C, and 100D each may include substantially the same throughput. Here, the throughput of each of the imprint chambers 100A, 100B, 100C, and 100D is T wph (wafer per hour). That is, each of the imprint chambers 100A, 100B, 100C, and 100D has a processing capacity sufficient to process T wafers in an hour. Accordingly, the total throughput of the imprint tool can be expressed as T*N. That is, all of the imprint chambers 100A, 100B,100C, and 100D can process, in total, T*N wafers in an hour. It is noted that the wafer discussed herein may be the substrate 120 as discussed in FIGS. 1 to 4, and the wafer can be processed using the imprint mask MA as discussed in FIGS. 1 to 4.

The operation S101 of method 1000 proceeds to operation S102 by setting a mask inspection interval. In some embodiments, one can set that each imprint mask (e.g., the imprint mask MA) needs to be inspected (e.g., using the imprint mask inspection chamber) after the imprint mask in an imprint chamber has processed Y wafers. As mentioned above, the throughput of each imprint chamber is T wph, and thus the mask inspection interval of the imprint mask after the imprint mask in an imprint chamber has processed Y wafers can be expressed as Y/T hours. Stated another way, the imprint mask in each imprint chamber should undergo an inspection process after performing imprint processes for Y/T hours. Moreover, when the number of the imprint chambers is N, it means that the inspection process and cleaning process is needed, in average, every Y/(T*N) hours.

On the other hand, the operation S101 of method 1000 may also proceed to operation S103 by estimating an inspection time of an imprint mask inspection chamber and a cleaning time of an imprint mask cleaning chamber. The imprint tool, such as the imprint tool 10A as shown in FIG. 8, is designed to have at least one imprint mask inspection chamber (e.g., the imprint mask inspection chamber 200 of FIG. 5) and least one imprint mask cleaning chamber (e.g., the imprint mask cleaning chamber 300 of FIG. 6). Based on the configurations of the imprint mask inspection chamber and the imprint mask cleaning chamber, the inspection time (or inspection duration) of the imprint mask inspection chamber and the cleaning time (or cleaning duration) of the imprint mask cleaning chamber can be estimated. In some embodiments, it is assumed that the inspection time of the imprint mask inspection chamber and the cleaning time of the imprint mask cleaning chamber are the same, which are both X hour. That is, the imprint mask inspection chamber is designated with an inspection duration of X hour for inspecting the imprint mask. Similarly, the imprint mask cleaning chamber is designated with a cleaning duration of X hour for cleaning the imprint mask.

The method 1000 proceeds to operation S104 by calculating a number of the imprint mask inspection chamber and a number of the imprint mask cleaning chamber. The number of the imprint mask inspection chamber and the number of the imprint mask cleaning chamber can be calculated based on the results generated from the operations S102 and S103. In some embodiments, it is assumed that the number of the imprint mask inspection chamber and the number of the imprint mask cleaning chamber are the same. For example, the number of the imprint mask inspection chamber and the number of the imprint mask cleaning chamber are both K. In some embodiments, the number K of the imprint mask inspection chamber and the imprint mask cleaning chamber can be expressed by X/[Y/(T*N)]=(X*T*N)/Y. More specifically, the number K is a smallest positive integer that is greater than or equal to (X*T*N)/Y.

As an example in FIG. 8. In operation S101, the imprint tool 10A is designed to have four imprint chambers 100A to 100D (N=4). If the throughput of each of the imprint chambers 100A to 100D is 20 wph (T=20), the total throughput of imprint tool 10A is 20 wph*4=80 wph (T*N). In operation S102, one can set that each imprint mask needs to be inspected after the imprint mask in an imprint chamber has processed 80 wafers (Y=80). Accordingly, the mask inspection interval of the imprint mask is 4 hours (Y/T=80/20). Moreover, because the number of the imprint chambers is 4, it means that the inspection process and cleaning process is needed, in average, every 1 hour (Y/(T*N)=80/(20*4)). In operation S103, an inspection time of an imprint mask inspection chamber and a cleaning time of an imprint mask cleaning chamber are estimated as 1 hour (X=1). As a result, in operation S104, by calculating (X*T*N)/Y=(1*20*4)/80=1, the actual number K of the imprint mask inspection chamber and the imprint mask cleaning chamber can be determined as a smallest positive integer greater than or equal to 1, which is 1 in this case (K=1).

The method 1000 proceeds to operation S105 by manufacturing an imprint tool. Based on the above calculation, one imprint mask inspection chamber and one imprint mask cleaning chamber are needed for the imprint tool 10A. Accordingly, the imprint tool 10A can be manufactured. The imprint tool 10A includes four imprint chambers 100A to 100D, one imprint mask inspection chamber 200A, and one imprint mask cleaning chamber 300A. It is noted that the imprint mask inspection chamber 200A and the imprint mask cleaning chamber 300A are similar to the imprint mask inspection chamber 200 and the imprint mask cleaning chamber 300 as described above, and thus relevant details will not be repeated for brevity.

The imprint tool 10A further includes a mask library 400, which is used to store additional imprint masks. In some embodiments, the mask library 400 may include more than three imprint masks for backup purpose. The imprint tool 10A further includes a transferring chamber 500 that are connected to the imprint chambers 100A to 100D, the imprint mask inspection chamber 200A, the imprint mask cleaning chamber 300A, the mask library 400. In some embodiments, the transferring chamber 500 includes a robot arm 502 and a robot arm 504. For example, the robot arm 502 has a range of motion sufficient to enter the imprint chambers 100A to 100D, the imprint mask inspection chamber 200A, the imprint mask cleaning chamber 300A, and the mask library 400 through the respective gates (e.g., the gates 110, 210, and 310 as discussed above), so as to transfer the imprint mask between any two of these chambers. That is, the imprint chambers 100A to 100D, the imprint mask inspection chamber 200A, the imprint mask cleaning chamber 300A, and the mask library 400 may be spatially communicated with the transferring chamber 500. In some embodiments, the mask library 400 may be immediately adjacent to the imprint mask cleaning chamber 300A, which is beneficial to shorten the distance for transferring a cleaned imprint mask from the imprint mask cleaning chamber 300A to the mask library 400.

The imprint tool 10A further includes a load port 600 connected to the transferring chamber 500. In some embodiments, the robot arm 504 of the transferring chamber 500 may be configured to transfer wafers between the load port 600 and one of the imprint chambers 100A to 100D. However, in other embodiments, the robot arm 504 of the transferring chamber 500 may also be configured to transfer imprint mask.

In some embodiments, the imprint chambers 100A to 100D are closer to the load port 600 than the imprint mask inspection chamber 200A, the imprint mask cleaning chamber 300A, and the mask library 400. This may shorten the distance for transferring wafer between load port 600 and the imprint chambers 100A to 100D.

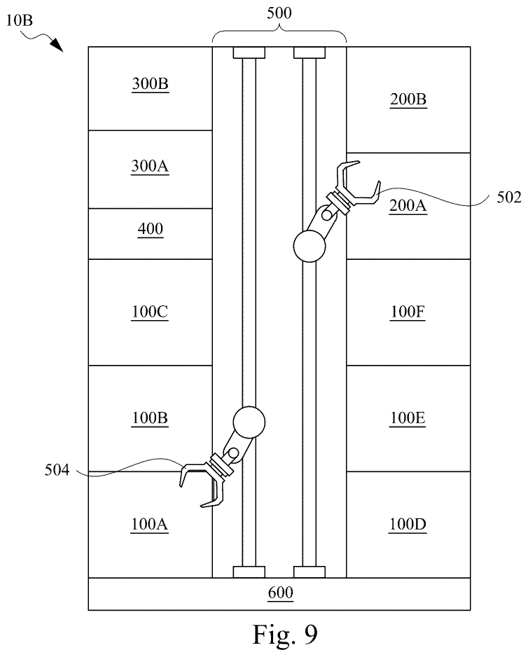

FIG. 9 is a schematic view of an imprint tool in accordance with some embodiments of the present disclosure. Shown there is an imprint tool 10B. In some embodiments, the imprint tool 10B can also be designed and be manufactured through the method 1000 as discussed in FIG. 7. Some elements of FIG. 9 have been described above with respect to FIG. 8, and thus relevant details will not be repeated for brevity.

In operation S101, the imprint tool 10B is designed to have six imprint chambers 100A, 100B, 100C, 100D, 100E, and 100F (N=6). If the throughput of each of the imprint chambers 100A to 100D is 20 wph (T=20), the total throughput of imprint tool 10A is 20 wph*6=120 wph (T*N). In operation S102, one can set that each imprint mask needs to be inspected after the imprint mask in an imprint chamber has processed 80 wafers (Y=80). Accordingly, the mask inspection interval of the imprint mask is 4 hours (Y/T=80/20). Moreover, because the number of the imprint chambers is 6, it means that the inspection process and cleaning process is needed, in average, every 0.66 hour (Y/(T*N)=80/(20*6)). In operation S103, an inspection time of an imprint mask inspection chamber and a cleaning time of an imprint mask cleaning chamber are estimated as 1 hour (X=1). As a result, in operation S104, by calculating (X*T*N)/Y=(1*20*6)/80=1.5, the actual number K of the imprint mask inspection chamber and the imprint mask cleaning chamber can be determined as a smallest positive integer greater than or equal to 1.5, which is 2 in this case (K=2).

Accordingly, based on the above calculation, two imprint mask inspection chamber and two imprint mask cleaning chamber are needed for the imprint tool 10B. As a result, in operation S105, the imprint tool 10B is manufactured. The imprint tool 10B includes six imprint chambers 100A to 100F, two imprint mask inspection chambers 200A and 200B, and two imprint mask cleaning chambers 300A and 300B.

The imprint tool 10B further includes a mask library 400, which is used to store additional imprint masks (e.g., imprint masks). The imprint tool 10B further includes a transferring chamber 500 that are connected to the imprint chambers 100A to 100F, the imprint mask inspection chamber 200A, the imprint mask cleaning chamber 300A, the mask library 400. The imprint tool 10B further includes a load port 600 connected to the transferring chamber 500.

TABLE 1

| | | | | | | Number of |
|---|---|---|---|---|---|---|
| | | | | | | mask |
| | | | Mask | | | inspection |
| | | Throughput | inspection / | | | chamber |
| | Number of | of each | Mask | | | and mask |
| | imprint | imprint | cleaning | Wafer | | cleaning |
| | chambers | chamber | time | processed | Calculation | chamber |
| Formula | N | T | X | Y | (T*N*X)/Y | |
| Condition 1 | 4 | 20 | 1 | 80 | 1 | 1 |
| Condition 2 | 6 | 20 | 1 | 80 | 1.5 | 2 |
| Condition 3 | 4 | 30 | 1 | 80 | 1.5 | 2 |
| Condition 4 | 4 | 20 | 1 | 40 | 2 | 2 |
| Condition 5 | 4 | 20 | 4 | 80 | 4 | 4 |
| Condition 6 | 6 | 30 | 1 | 80 | 2.25 | 3 |
| Condition 7 | 4 | 25 | 2 | 50 | 4 | 4 |
| Condition 8 | 4 | 25 | 4 | 100 | 4 | 4 |

It is understood that the examples of FIGS. 8 and 9 are merely used to explain. The numbers of the imprint mask inspection chamber(s) and the imprint mask cleaning chamber(s) may vary case by case. For example, table 1 shows eight different conditions and the calculated numbers of the imprint mask inspection chamber(s) and the imprint mask cleaning chamber(s), in which conditions 1 and 2 have been discussed in FIGS. 8 and 9, respectively.

In condition 3, the imprint tool is designed to have four imprint chambers (N=4), in which each of the imprint chambers is 30 wph (T=30). Each imprint mask will be inspected after the imprint mask in an imprint chamber has processed 80 wafers (Y=80). An inspection time of an imprint mask inspection chamber and a cleaning time of an imprint mask cleaning chamber are estimated as 1 hour (X=1). As a result, by calculating (X*T*N)/Y=(1*30*4)/80=1.5, the actual number K of the imprint mask inspection chamber and the imprint mask cleaning chamber can be determined as a smallest positive integer greater than or equal to 1.5, which is 2 in this case (K=2).

In condition 4, the imprint tool is designed to have four imprint chambers (N=4), in which each of the imprint chambers is 20 wph (T=20). Each imprint mask will be inspected after the imprint mask in an imprint chamber has processed 40 wafers (Y=40). An inspection time of an imprint mask inspection chamber and a cleaning time of an imprint mask cleaning chamber are estimated as 1 hour (X=1). As a result, by calculating (X*T*N)/Y=(1*20*4)/40=2, the actual number K of the imprint mask inspection chamber and the imprint mask cleaning chamber can be determined as a smallest positive integer greater than or equal to 2, which is 2 in this case (K=2).

In condition 5, the imprint tool is designed to have four imprint chambers (N=4), in which each of the imprint chambers is 20 wph (T=20). Each imprint mask will be inspected after the imprint mask in an imprint chamber has processed 80 wafers (Y=80). An inspection time of an imprint mask inspection chamber and a cleaning time of an imprint mask cleaning chamber are estimated as 4 hours (X=4). As a result, by calculating (X*T*N)/Y=(4*20*4)/80=4, the actual number K of the imprint mask inspection chamber and the imprint mask cleaning chamber can be determined as a smallest positive integer greater than or equal to 4, which is 4 in this case (K=4).

In condition 6, the imprint tool is designed to have six imprint chambers (N=6), in which each of the imprint chambers is 30 wph (T=30). Each imprint mask will be inspected after the imprint mask in an imprint chamber has processed 80 wafers (Y=80). An inspection time of an imprint mask inspection chamber and a cleaning time of an imprint mask cleaning chamber are estimated as 1 hour (X=1). As a result, by calculating (X*T*N)/Y=(1*30*6)/80=2.25, the actual number K of the imprint mask inspection chamber and the imprint mask cleaning chamber can be determined as a smallest positive integer greater than or equal to 2.25, which is 3 in this case (K=3).

In condition 7, the imprint tool is designed to have four imprint chambers (N=4), in which each of the imprint chambers is 25 wph (T=25). Each imprint mask will be inspected after the imprint mask in an imprint chamber has processed 50 wafers (Y=50). An inspection time of an imprint mask inspection chamber and a cleaning time of an imprint mask cleaning chamber are estimated as 2 hours (X=2). As a result, by calculating (X*T*N)/Y=(2*25*4)/50=4, the actual number K of the imprint mask inspection chamber and the imprint mask cleaning chamber can be determined as a smallest positive integer greater than or equal to 4, which is 4 in this case (K=4).

In condition 8, the imprint tool is designed to have four imprint chambers (N=4), in which each of the imprint chambers is 25 wph (T=25). Each imprint mask will be inspected after the imprint mask in an imprint chamber has processed 50 wafers (Y=100). An inspection time of an imprint mask inspection chamber and a cleaning time of an imprint mask cleaning chamber are estimated as 4 hours (X=4). As a result, by calculating (X*T*N)/Y=(4*25*4)/100=4, the actual number K of the imprint mask inspection chamber and the imprint mask cleaning chamber can be determined as a smallest positive integer greater than or equal to 4, which is 4 in this case (K=4).

In some embodiments, no matter what the numbers of the imprint chamber(s), the imprint mask inspection chamber(s), and the imprint mask cleaning chamber(s) are, the imprint tool may include a single mask library 400, a single transferring chamber 500, and a single load port 600.

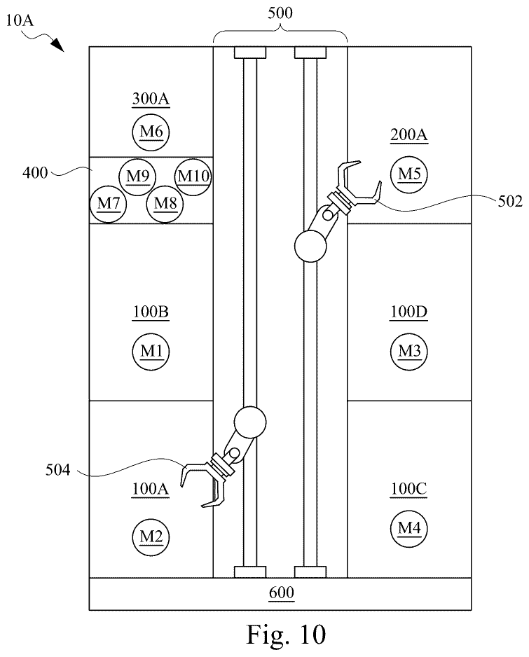

FIGS. 10 to 12 illustrate schematic views of an imprint tool at various stages of operating the imprint tool in accordance with some embodiments of the present disclosure. It is noted that the method of FIGS. 10 to 12 will be discussed by using the imprint tool 10A of FIG. 8 as an example.

Reference is made to FIG. 10. The imprint tool 10A includes ten imprint masks M1 to M10 located at different chambers of the imprint tool 10A. For example, the imprint masks M1, M2, M3, and M4 are disposed in the imprint chambers 100B, 100A, 100D, and 100C, respectively. Moreover, the imprint chambers 100B, 100A, 100D, and 100C may be used to perform imprint processes to the respective wafers by using the imprint masks M1, M2, M3, and M4, respectively.

On the other hand, the imprint mask M5 is disposed in the imprint mask inspection chamber 200A, and may undergo an inspection process as discussed in FIG. 5. The imprint mask M6 is disposed in the imprint mask cleaning chamber 300A, and may undergo a cleaning process as discussed in FIG. 6. The imprint masks M7, M8, M9, and M10 are stored in the mask library 400.

It is noted that, because the imprint chambers 100A to 100D, the imprint mask inspection chamber 200A, and the imprint mask cleaning chamber 300A are integrated in a same imprint tool 10A, and thus the imprint processes of the imprint chambers 100A to 100D, the inspection process of the imprint mask inspection chamber 200A, and the cleaning process of the imprint mask cleaning chamber 300A may be performed simultaneously.

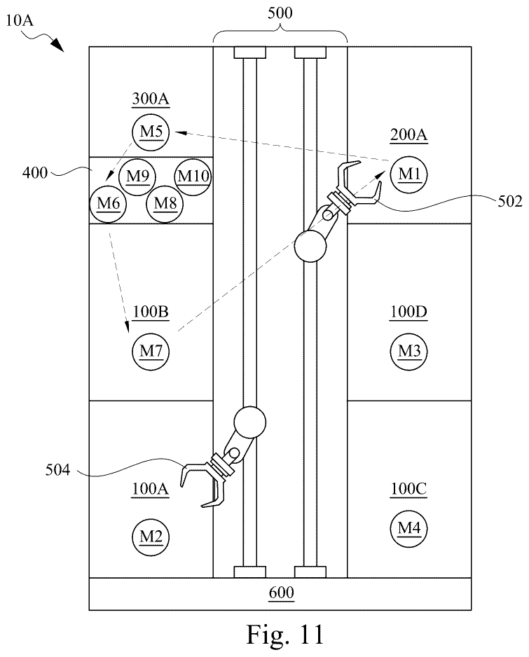

Reference is made to FIG. 11. Once the imprint mask M5 in the imprint mask inspection chamber 200A has finished the inspection process, the imprint mask M6 in the imprint mask cleaning chamber 300A has finished the cleaning process, and the imprint mask M1 in the imprint chamber 100B has reached the mask inspection interval (e.g., the imprint mask M1 has been used for Y/T hours in the imprint chamber 100B), the imprint mask M6 is first transferred to the mask library 400, the imprint mask M5 is then transferred to the empty imprint mask cleaning chamber 300A, the imprint mask M1 is then transferred to the empty imprint mask inspection chamber 200A, and the imprint mask M7 in the mask library 400 is then transferred to the empty imprint chamber 100B. It is understood that, during the transfer of the imprint masks M1, M5, M6, and M7, the imprint chambers 100A, 100C, and 100D may continuously perform imprint processes to the respective wafers using the imprint masks M2, M4, and M3, respectively.

After the imprint masks M7, M1, and M5 are transferred to the imprint chamber 100B, the imprint mask inspection chamber 200A, and the imprint mask cleaning chamber 300A, respectively, an imprint process can be performed in the imprint chamber 100B using the imprint mask M7, an inspection process can be performed to the imprint mask M1 through the imprint mask inspection chamber 200A, and a cleaning process can be performed to the imprint mask M5 through the imprint mask cleaning chamber 300A.

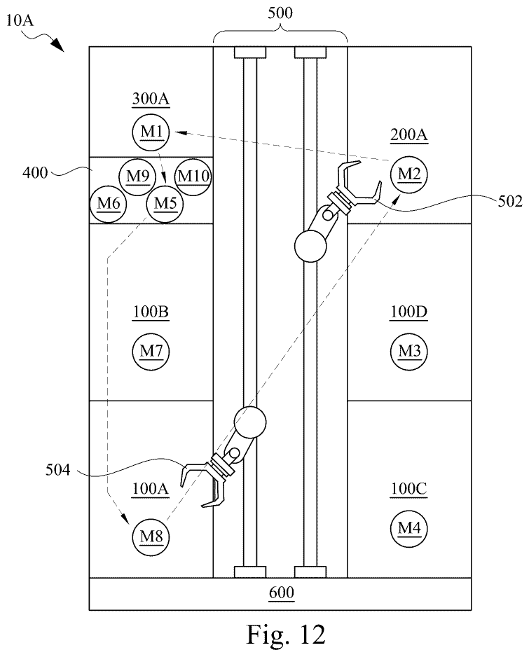

Reference is made to FIG. 12 Once the imprint mask M1 in the imprint mask inspection chamber 200A has finished the inspection process, the imprint mask M5 in the imprint mask cleaning chamber 300A has finished the cleaning process, and the imprint mask M2 in the imprint chamber 100A has reached the mask inspection interval (e.g., the imprint mask M2 has been used for Y/T hours in the imprint chamber 100A), the imprint mask M5 is first transferred to the mask library 400, the imprint mask M1 is then transferred to the empty imprint mask cleaning chamber 300A, the imprint mask M2 is then transferred to the empty imprint mask inspection chamber 200A, and the imprint mask M8 in the mask library 400 is then transferred to the empty imprint chamber 100A. It is understood that, during the transfer of the imprint masks M1, M2, M5, and M8, the imprint chambers 100B, 100C, and 100D may continuously perform imprint processes to the respective wafers using the imprint masks M7, M4, and M3, respectively.

After the imprint masks M8, M2, and M1 are transferred to the imprint chamber 100A, the imprint mask inspection chamber 200A, and the imprint mask cleaning chamber 300A, respectively, an imprint process can be performed in the imprint chamber 100A using the imprint mask M8, an inspection process can be performed to the imprint mask M2 through the imprint mask inspection chamber 200A, and a cleaning process can be performed to the imprint mask M1 through the imprint mask cleaning chamber 300A.

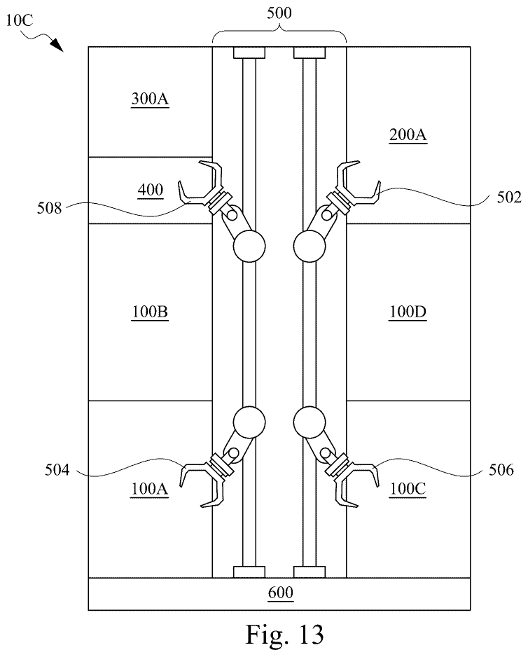

FIG. 13 is a schematic view of an imprint tool in accordance with some embodiments of the present disclosure. Shown there is an imprint tool 10C, the imprint tool 10C of FIG. 13 is similar to the imprint tool 10A of FIG. 8, the difference between FIG. 13 and FIG. 8 is that the transferring chamber 500 includes robot arms 502, 504, 506, and 508, in which each of the robot arms 502, 504, 506, and 508 has a range of motion sufficient to enter the imprint chambers 100A to 100D, the imprint mask inspection chamber 200A, the imprint mask cleaning chamber 300A, and the mask library 400.

As discussed in FIGS. 11 and 12, it can be seen that the transfer of the imprint masks may include four steps, which includes transferring an imprint mask from the imprint mask cleaning chamber 300A to the mask library 400 (step 1), transferring an imprint mask from the imprint mask inspection chamber 200A to the imprint mask cleaning chamber 300A (step 2), transferring an imprint mask from one of the imprint chambers 100A to 100D to the imprint mask inspection chamber 200A (step 3), and then transferring an imprint mask from the mask library 400 to the one of the imprint chambers 100A to 100D (step 4). Because the transferring chamber 500 includes four robot arms 502, 504, 506, and 508, the robot arms 502, 504, 506, and 508 can be used respectively for the steps 1 to 4 as discussed above to transfer the respective imprint masks to the target chambers, which will improve the operation efficiency of the imprint tool.

FIG. 14 is a block diagram of an imprint tool in accordance with some embodiments of the present disclosure. Shown there is an imprint tool 10D, the imprint tool 10D may be similar to the imprint tools 10A, 10B, and 10C as discussed above. The imprint tool 10D includes at least one imprint chamber 100, at least one imprint mask inspection chamber 200, at least one imprint mask cleaning chamber 300, a mask library 400, a transferring chamber 500, and a load port 600. The imprint tool 10D further includes a control system 700 that is electrically connected to the imprint chamber 100, the imprint mask inspection chamber 200, the imprint mask cleaning chamber 300, the mask library 400, the transferring chamber 500, and the load port 600.

In some embodiments, the control system 700 may a controller and a computer readable storage medium encoded with, i.e., storing, a computer program code, i.e., a set of executable instructions. The controller is electrically coupled to the computer readable storage medium. The controller is configured to execute the computer program code encoded in the computer readable storage medium in order to cause the control system 700 to be used to performing the all operations as discussed above. For example, the control system 700 may be configured to control the imprint process as discussed in FIGS. 1 to 4, the inspection process as discussed in FIG. 5, the cleaning process as discussed in FIG. 6, and the transfer of the imprint masks as discussed in FIGS. 10 to 12.

In some embodiments, the controller is a central processing unit (CPU), a multi-processor, a distributed processing system, an application specific integrated circuit (ASIC), and/or a suitable processing unit. In some embodiments, the computer readable storage medium includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium includes a compact disk-read only memory (CD-ROM), a compact disk-read/write (CD-R/W), and/or a digital video disc (DVD).

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide an all-in-one (AIO) nano imprint lithography (NIL) tool by integrating imprint chambers, at least one imprint mask inspection chamber, at least one imprint mask cleaning chamber, a mask library, and a transferring chamber in a single imprint tool. Moreover, embodiments of the present disclosure also provide a method for designing the imprint tool according to different parameters of the imprint tool, so as to precisely control the numbers of the imprint mask inspection chamber(s) and the imprint mask cleaning chamber(s). With such configuration, continuous real-time mask monitoring and maintenance can be achieved, and backup masks can be stored in mask library to ensure mask/tool availability. Accordingly, good quality control of imprint masks lead to a more consistent patterning performance.

In some embodiments of the present disclosure, a method includes performing imprint processes in imprint chambers of an imprint tool; performing an inspection process to a first imprint mask in at least one inspection chamber of the imprint tool; performing a cleaning process to a second imprint mask in at least one cleaning chamber of the imprint tool; transferring the second imprint mask from the at least one cleaning chamber to a mask library of the imprint tool; transferring the first imprint mask from the at least one inspection chamber to the cleaning chamber; transferring a third imprint mask from a first one of the imprint chambers to the at least one inspection chamber; and transferring a fourth imprint mask from the mask library to the first one of the imprint chambers.

In some embodiments, the imprint processes, the inspection process, and the cleaning process are performed simultaneously.

In some embodiments, the imprint tool comprises more than one inspection chamber and more than one cleaning chamber.

In some embodiments, during transferring the first, second, third, and fourth imprint masks, a second one of the imprint chambers continuously performs a respective imprint process.

In some embodiments, transferring the first, second, third, and fourth imprint masks are performed using different robot arms.

In some embodiments, wherein a number of the imprint chambers is N, each of the imprint chambers is able to process T wafers in an hour, an imprint mask in one of the imprint chambers is set to be inspected after processing Y wafers, an inspection time of the inspection process is X hour, and a number of the least one inspection chamber is a smallest positive integer that is greater than or equal to (X*T*N)/Y.

In some embodiments, a number of the at least one inspection chamber is the same as a number of the at least one of the cleaning chamber.

In some embodiments of the present disclosure, a method includes determining a number of imprint chambers of an imprint tool, wherein the number of the imprint chambers is N, and each of the imprint chambers is able to process T wafers in an hour; setting an imprint mask in one of the imprint chambers to be inspected after processing Y wafers; estimating an inspection time for inspecting the imprint mask in at least one inspection chamber, wherein the inspection time is X hour; and manufacturing the imprint tool having the imprint chambers and the at least one inspection chamber, wherein a number of the at least one inspection chamber is a smallest positive integer that is greater than or equal to (X*T*N)/Y.

In some embodiments, manufacturing the imprint tool is performed such that the imprint tool has at least one cleaning chamber configured to clean the imprint mask.

In some embodiments, a number of the at least one cleaning chamber is the same as the number of the at least one inspection chamber.

In some embodiments, the number of the at least one cleaning chamber and the number of the at least one inspection chamber are more than one.

In some embodiments, manufacturing the imprint tool is performed such that the imprint tool has a mask library configured to store additional imprint masks.

In some embodiments, manufacturing the imprint tool is performed such that the imprint tool has a transferring chamber communicated with the imprint chambers and the at least one inspection chamber.

In some embodiments, the transferring chamber comprises at least one robot arm, wherein the at least one robot arm is able to enter the imprint chambers and the at least one inspection chamber.

In some embodiments, the transferring chamber comprises more than one robot arm.

In some embodiments of the present disclosure, an imprint apparatus includes a transferring chamber; imprint chambers spatially communicated with the transferring chamber; at least one imprint mask inspection chamber spatially communicated with the transferring chamber; and at least one imprint mask cleaning chamber spatially communicated with the transferring chamber.

In some embodiments, a number of the imprint chambers is N, each of the imprint chambers has a processing capacity sufficient to process T wafers in an hour, an imprint mask in one of the imprint chambers is designated for inspection in the imprint mask inspection chamber after Y wafers have been processed, the imprint mask inspection chamber is designated with an inspection duration of X hour for the imprint mask, and a number of the least one imprint mask inspection chamber is a smallest positive integer that is greater than or equal to (X*T*N)/Y.

In some embodiments, a number of the at least one imprint mask cleaning chamber is the same as the number of the at least one imprint mask inspection chamber.

In some embodiments, the number of the at least one imprint mask cleaning chamber and the number of the at least one imprint mask inspection chamber each is more than one.

In some embodiments, the transferring chamber comprises at least one robot arm, wherein the robot arm has a range of motion sufficient to enter the imprint chambers, the at least one imprint mask inspection chamber, and the at least one imprint mask cleaning chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing imprint processes in imprint chambers of an imprint tool;
performing an inspection process to a first imprint mask in at least one inspection chamber of the imprint tool;
performing a cleaning process to a second imprint mask in at least one cleaning chamber of the imprint tool;
transferring the second imprint mask from the at least one cleaning chamber to a mask library of the imprint tool;
transferring the first imprint mask from the at least one inspection chamber to the cleaning chamber;
transferring a third imprint mask from a first one of the imprint chambers to the at least one inspection chamber; and
transferring a fourth imprint mask from the mask library to the first one of the imprint chambers.

2. The method of claim 1, wherein the imprint processes, the inspection process, and the cleaning process are performed simultaneously.

3. The method of claim 1, wherein the imprint tool comprises more than one inspection chamber and more than one cleaning chamber.

4. The method of claim 1, wherein during transferring the first, second, third, and fourth imprint masks, a second one of the imprint chambers continuously performs a respective imprint process.

5. The method of claim 1, wherein transferring the first, second, third, and fourth imprint masks are performed using different robot arms.

6. The method of claim 1, wherein:
a number of the imprint chambers is N,
each of the imprint chambers is able to process T wafers in an hour,
an imprint mask in one of the imprint chambers is set to be inspected after processing Y wafers,
an inspection time of the inspection process is X hour, and
a number of the least one inspection chamber is a smallest positive integer that is greater than or equal to (X*T*N)/Y.

7. The method of claim 6, wherein a number of the at least one inspection chamber is the same as a number of the at least one of the cleaning chamber.

8. A method, comprising:
determining a number of imprint chambers of an imprint tool, wherein the number of the imprint chambers is N, and each of the imprint chambers is able to process T wafers in an hour;
setting an imprint mask in one of the imprint chambers to be inspected after processing Y wafers;
estimating an inspection time for inspecting the imprint mask in at least one inspection chamber, wherein the inspection time is X hour; and
manufacturing the imprint tool having the imprint chambers and the at least one inspection chamber, wherein a number of the at least one inspection chamber is a smallest positive integer that is greater than or equal to (X*T*N)/Y.

9. The method of claim 8, wherein manufacturing the imprint tool is performed such that the imprint tool has at least one cleaning chamber configured to clean the imprint mask.

10. The method of claim 9, wherein a number of the at least one cleaning chamber is the same as the number of the at least one inspection chamber.

11. The method of claim 10, wherein the number of the at least one cleaning chamber and the number of the at least one inspection chamber are more than one.

12. The method of claim 8, wherein manufacturing the imprint tool is performed such that the imprint tool has a mask library configured to store additional imprint masks.

13. The method of claim 8, wherein manufacturing the imprint tool is performed such that the imprint tool has a transferring chamber communicated with the imprint chambers and the at least one inspection chamber.

14. The method of claim 13, wherein the transferring chamber comprises at least one robot arm, wherein the at least one robot arm is able to enter the imprint chambers and the at least one inspection chamber.

15. The method of claim 14, wherein the transferring chamber comprises more than one robot arm.

16. An imprint apparatus, comprising:
a transferring chamber;
imprint chambers spatially communicated with the transferring chamber;
at least one imprint mask inspection chamber spatially communicated with the transferring chamber; and
at least one imprint mask cleaning chamber spatially communicated with the transferring chamber.

17. The imprint apparatus of claim 16, wherein
a number of the imprint chambers is N,
each of the imprint chambers has a processing capacity sufficient to process T wafers in an hour,
an imprint mask in one of the imprint chambers is designated for inspection in the imprint mask inspection chamber after Y wafers have been processed,
the imprint mask inspection chamber is designated with an inspection duration of X hour for the imprint mask, and
a number of the least one imprint mask inspection chamber is a smallest positive integer that is greater than or equal to (X*T*N)/Y.

18. The imprint apparatus of claim 17, wherein a number of the at least one imprint mask cleaning chamber is the same as the number of the at least one imprint mask inspection chamber.

19. The imprint apparatus of claim 18, wherein the number of the at least one imprint mask cleaning chamber and the number of the at least one imprint mask inspection chamber each is more than one.

20. The imprint apparatus of claim 16, wherein the transferring chamber comprises at least one robot arm, wherein the robot arm has a range of motion sufficient to enter the imprint chambers, the at least one imprint mask inspection chamber, and the at least one imprint mask cleaning chamber.
